(19) United States
(12) Patent Application Publication
(10) Pub. No.: US 2010/0159816 A1
(43) Pub. Date: Jun. 24, 2010

(54) CONVERGING SEGMENTS COOLING

(75) Inventors: Harald Huels, Boolingen (DE); Dierer Staiger, Boolingen (DE)

Correspondence Address: McGinn Intellectual Property Law Group, PLLC, 8321 Old Courthouse Road, Suite 200, Vienna, VA, 22182-3817, US

(73) Assignee: INTERNATIONAL BUSINESS MACHINES CORPORATION, ARMONK, NY (US)

(21) Appl. No.: 12/342,797

(22) Filed: Dec. 23, 2008

(51) Int. Cl. H05K 7/20

(52) U.S. Cl. 454/184

(57) ABSTRACT

A method of cooling a complex electronic system includes preventing system air from passing through a front side and a rear side of a server system main board, organizing a plurality of electronic segments of the server system main board, providing cool air horizontally to the server system main board through a cool air intake provided at a position located underneath the front side and at a bottom side of the server system main board, using the cool air intake to provide the cool air to a plurality of cooling segments that redirect the cool air vertically at a 90° angle, and using a hot air exhaust after the hot air reaches the top side of the server system main board to redirect the hot air horizontally at a 90° angle and exhaust the hot air.

### BACKGROUND OF THE INVENTION

1. Field of the Invention

The present invention generally relates to system packaging and cooling solutions, and more specifically to a method and apparatus for cost effective and efficient cooling of complex electronic systems such as 1U to nU server systems or electronic control systems as well as card-on-board systems such as Blade systems.

2. Description of the Related Art

Server racks are conventionally used to house a plurality of electronic modules in a specific storage location. Due to the plurality of electronic modules housed in conventional server racks, optimizing the cooling of these racks is a challenging goal, especially when taking into account packaging requirements and heat dissipation properties of servers.

The conventional cooling of server racks, such as blade systems, is accomplished by forcing a cool air-stream along the “length” side of the system motherboard. Cool air is aspirated at the front of the rack to pick up heat energy that is required to be dissipated from the electronic components. The heat energy dissipating from the electronic components transforms the cool air into hot air, which is expelled at the rear side of the system. Conventional systems require low air-stream impedance front system board entry covers, such as perforated sheet metal. Conventional systems also require uncovered openings between input/output (I/O) connectors at the rear end of the rack.

Due to an increased production of heat to be dissipated by servers which are increasingly more powerful, motherboard architecture is more commonly driven by thermal requirements. This change in motherboard architecture requires compromises to be made to ensure effective signal wiring and protect signal intergrity. These compromises lead to increase wiring complexity and, as a consequence, require an increased number of motherboard layers, leading to higher costs.

Moreover, the conventional cool airstream needs to travel through the entire motherboard length. To guarantee the required cooling for all components on the board, the air pressure must be high enough to cope with the accumulated airstream resistance. An increased air pressure typically implies increased energy consumption.

Further, the cool air input stream entering at the system front typically requires unconstrained airstream intake. Space and areas for front-side accessible feature cards or front-side wiring is limited to a minimum.

Another conventional solution is provided by a system disclosed in U.S. Patent Publication No. 2005/0247067 A1, which attempts to overcome detracted cooling of the electronic components positioned in series within the main cool air stream. The system board still requires an ‘air open’ front side of the system board with the cool air traveling the “length” side of the system board—exiting on the ‘air open’ rear end of the system board.

To overcome a cooling disadvantage for components having a position ‘further downstream’ in the cool air pass, this conventional solution applies a Thermoelectric Cooler (TEC) module to arrange to ‘bypass’ some of the pre-heated air, thus providing improved cooling for disadvantaged components.

However, the TEC modules generate a significant amount of additional heat. Further, conventional server systems are typically operated in a maximum cool air stream. Thus, the additional dissipation loss generated by the TEC modules cannot be tolerated by most systems.

### SUMMARY OF THE INVENTION

In view of the foregoing and other exemplary problems, drawbacks, and disadvantages of the conventional methods and structures, an exemplary object of the present invention is to provide an apparatus, system, and method of cooling complex electronic systems efficiently and at low cost.

An exemplary embodiment of a method of cooling a complex electronic system includes preventing system air from passing through a front side and a rear side of a server system main board, organizing a plurality of electronic segments of the server system main board, the organizing the plurality of electronic segments including providing a first segment at the rear side of the server system main board, the first segment including input/output components connected directly to system processors, providing a second segment at a middle portion of the server system main board, the second segment including the system processors, and providing a third segment at the front side of the server system main board, the third segment including a memory subsystem and a plurality of front-side accessible components being one of connected to the system processors and connected to the input/output components, providing cool air horizontally to a cool air intake provided at a position located underneath the front side and at a bottom side of the server system main board, the cool air being pulled through the server system main board by a blower unit positioned adjacent to a hot air exhaust and a top side and the rear side of the server system main board, using the cool air intake to provide the cool air to a plurality of cooling segments that redirect the cool air vertically at a 90° angle, the using the cool air intake such that the cool air vertically crosses the server system main board in the plurality of cooling segments from the bottom side of the server system main board to the top side of the server system main board, the cool air removing heat energy from a plurality of components provided on the server system main board such that the cool air becomes hot air when reaching the top side of the server system main board, the plurality of cooling segments separated by a plurality of air guide fins, the cool air intake comprising a segment airflow control flap that adjusts a distribution of the cool air to the plurality of cooling segments, the plurality of cooling segments respectively associated with the plurality of electronic segments, and using a hot air exhaust after the hot air reaches the top side of the server system main board to redirect the hot air horizontally at a 90° angle and exhaust the hot air, the hot air exhaust provided at a position located above the rear side of the server system main board, at the top side of the server system main board, and on an opposite side of the plurality of cooling segments from the cool air intake, the hot air exhaust including a controllable exhaust throttle flap that restricts a flow of hot air emanating from one of the plurality of cooling segments. The cool air and the hot air include an airstream. The cool air intake and the hot air exhaust utilize polished air guidance to prevent a resistance of the airstream, provide the airstream at a high speed, lower noise caused by the airstream, and reduce a loss of the cool air by the cool air intake. The air guide fins, the cool air intake, and the hot air exhaust include an unruffled surface.

According to the exemplary embodiments of the present invention, horizontal-vertical-horizontal airstream redirection takes place. The system server system main board front and rear sides in the exemplary embodiment are air tight. The cool air intake is located at the system front underneath the server system main board front side. The cool air intake duct is designed to guide the airstream by 90° leading to a vertical airstream traveling over the server system main board from bottom to top. At the top of the server system main board, a second airstream redirection ending at a hot air exhaust above the server system main board is provided. Thus, the cooling of electronic components may be fulfilled without being handicapped by the architecture of those components.

### BRIEF DESCRIPTION OF THE DRAWINGS

The foregoing and other exemplary purposes, aspects and advantages will be better understood from the following detailed description of exemplary embodiments of the invention with reference to the drawings, in which:

FIG. 1 illustrates an exemplary embodiment of a server system main board 100 with a typical electronic system structure indicating the major component groups, the interrelation of the major component groups, and the associated signal correspondence and board wiring requirements of the major component groups;

FIG. 2 illustrates an exemplary embodiment of Horizontal-Vertical-Horizontal airstream redirection of the present invention;

FIG. 3 illustrates an exemplary embodiment of the server system main board 100 layout of the present invention;

FIG. 4 illustrates an exemplary embodiment of converging system cooling (CSC) using system design specific cooling segments 401, 402, 403 for the server system main board 100 layout of the present invention;

FIG. 5 illustrates an exemplary embodiment of an air guide fin of the converging system cooling (CSC) using a system design-specific cooling segment of the present invention;

FIG. 6 illustrates an exemplary embodiment of the CSC airflow convergence control elements of the present invention;

FIG. 7 illustrates an exemplary embodiment of the CSC airflow throttle element 701;

FIG. 8 illustrates an exemplary embodiment of a method 800 of the present invention; and

FIG. 9 illustrates an exemplary embodiment of a system 900 of the present invention.

### DETAILED DESCRIPTION OF EXEMPLARY EMBODIMENTS OF THE INVENTION

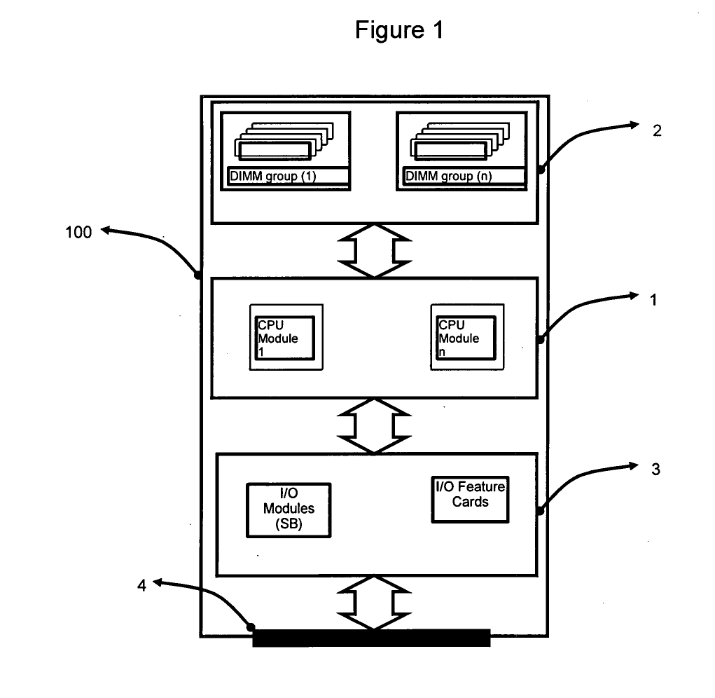

Referring now to the drawings, and more particularly to FIGS. 1-8, there are shown exemplary embodiments of the structures and method according to the present invention. For simplicity of description, all embodiments of the present invention are exemplarily applied to Blade Servers and a Blade Center Chassis. One of ordinary skill in the art would clearly realize that the present invention is not limited to this application. On the contrary, the present invention is advantageously applicable to all simple or complex electronic systems that utilize electronic components with significantly varying energy consumptions such that an active cooling solution is required. Examples of applicable systems are 1U to nU rack-mount systems, card-on-board systems (e.g., Blade), high performance energy industrial electronic systems, and high performance graphic systems, as well as typical workstation and desktop computers.

FIG. 1 illustrates an exemplary embodiment of a server system main board 100 with a typical electronic system structure indicating the major component groups, the interrelation of the major component groups, and the associated signal correspondence and board wiring requirements of the major component groups. Regardless of the server system form factor, the server system main board 100 of FIG. 1 exemplarily includes system processors 1 that are connected to a memory subsystem 2 and a server I/O subsystem 3. The system processors 1 represent the heart of the server system main board 100. The memory subsystem 2, depending on the chip architecture of the system processors 1, is either directly connected to the system processors 1 or connected to the system processors 1 by a separate bridge/memory controller (not shown).

The connectivity between the system processors 1 and the memory subsystem 2 is exclusive. Since there are no other connections to the memory subsystem 2, the memory subsystem 2 can be considered a wiring end-point that is best positioned at an area of the server system main board 100 where frequent access is not required.

The system processors 1 are communicating with and connected to the server I/O subsystem 3. A board layout positioning the system processors 1 in the center of the server system main board 100 between the memory subsystem 2 and the server I/O subsystem 3 is an example of an effective wiring model that provides a potential for reducing an amount of required board layers. The server I/O subsystem 3, which exemplarily and typically provides connectivity to systems outside the server system main board 100, is closely positioned to a connector area 4 of the server system main board 100 for relatively easy access

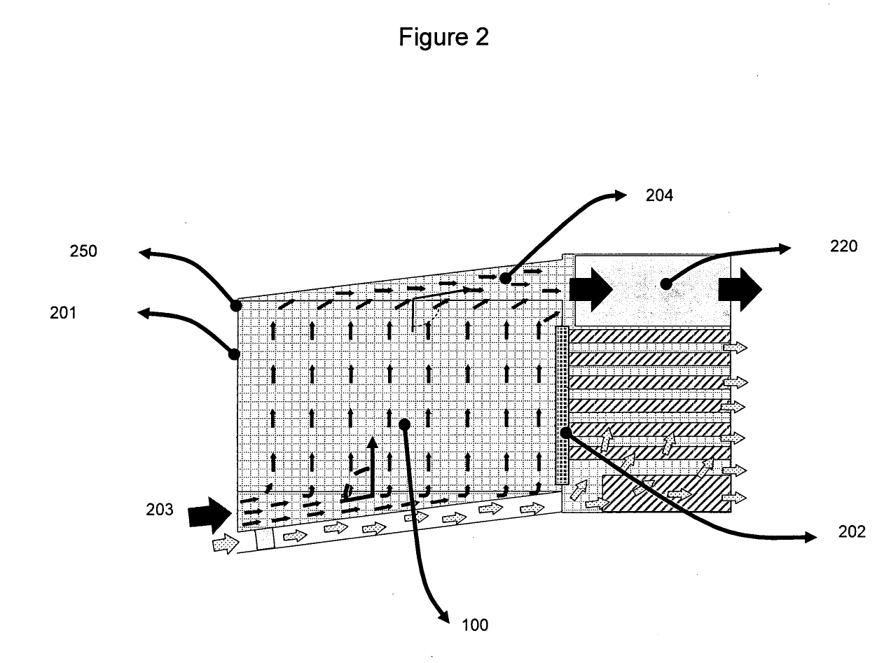

FIG. 2 illustrates an exemplary embodiment of Horizontal-Vertical-Horizontal airstream redirection of the present invention. The front 201 and rear 202 sides of the server system main board 100 are airtight—no air is entering or leaving at these boundaries of the server system main board 100.

The cool air intake 203 is located at the front of the server system main board 100 underneath the front side 201 of the server system main board 100. The cool air intake 203 is designed to redirect the airstream by 90°, leading to a vertical airstream traveling the server system main board 100 from bottom to top. At the top of the server system main board 100, a second airstream redirection is provided by a hot air exhaust 204 above the rear side 202 of the server system main board 100.

The cool air intake 203 and the hot air exhaust 204 are exemplarily built utilizing polished air guidance with very low air resistance, thus leading to high air speed, lowered airstream noise, and a reduced amount of loss by the cool air intake 203. One of ordinary skill in the art, however, could implement another method of providing very low air resistance, high air speed, lowered airstream noise, and a reduced amount of loss by the cool air intake 203. To ‘feed’ these Segments to the board area specific requirements with cooling air—the cool air intake 203 is provided with horizontal and corresponding vertical ducts to allow separated airstreams specific to an area of the server system main board 100.

The cooling air vertically crosses the server system main board 100 from bottom to top. While doing this, the cooling air carries heat energy taken from the various components of the server system main board 100. After being exposed to the heat energy, the cooling air changes to a hot air and is recollected by a hot air exhaust 204. The vertical and horizontal ducts of the hot air exhaust 204 redirect the air again by 90°, horizontally leading the hot air to the air exit of the hot air exhaust 204 at the rear 202 of the server system main board 100.

Redirection of the cooling airstream to force the cooling air to vertically cross the server system main board 100 at the long side results in a lowered aerodynamic resistance. The advantages of this are increased cooling efficiency, reduced noised level, and a potential increase in system performance.

In Blade systems, the cooling airstream is generated by blower units 220 at the rear of a Blade Center chassis 250. The blower unit 220 is providing all Blades within a rack with low pressure. In 1U to nU rack-mount systems, each rack unit is typically provided with its dedicated multiple but smaller blowers. The blower unit 220 pulls air through the cool air intake 203 and the hot air exhaust 204.

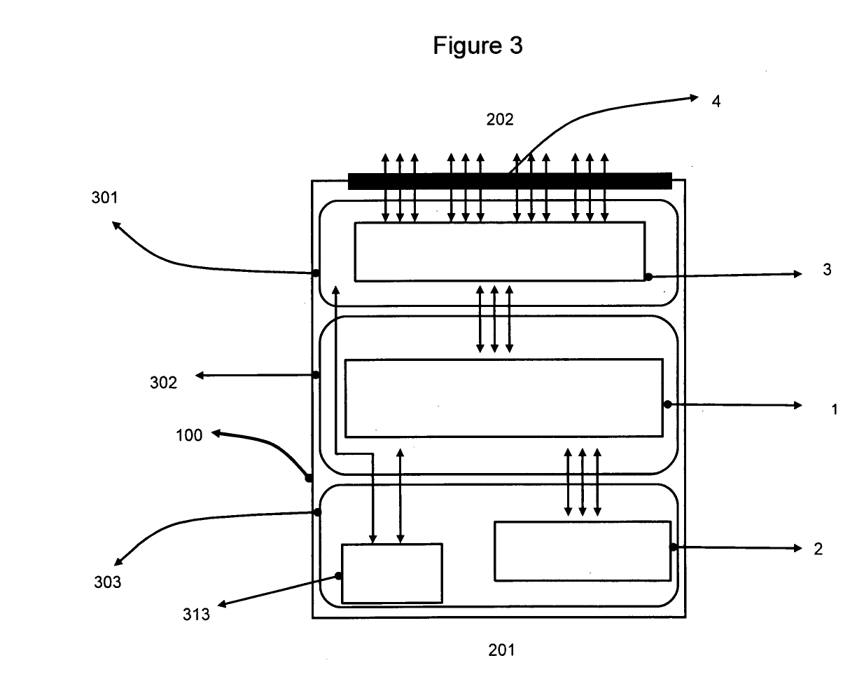

FIG. 3 illustrates an exemplary embodiment of the server system main board 100 layout of the present invention. The system processors 1 and closely related electronics are located within the second segment 302. The second segment 302 represents the electronics demanding the highest energy consumption.

Optimally positioned for best connectivity to the system processors 1, the memory subsystem 2 is located in the third segment 303. The components of the memory subsystem 2 show fairly high energy demand. Also positioned within the third segment 303 are front side accessible components 313. Typically, the front side accessible components 313 show comparably lower energy consumption. If they are directly related to the system processors 1 and not I/O related, the front side accessible components 313 are connected to the system processors 1.

The first segment 301 holds all major I/O components including the server I/O subsystem 3. On one side, these components are connected directly to the system processors 1. On the I/O side location, the I/O components are closed to the corresponding I/O connectors at the rear end of the server system main board 100. The I/O components typically require low electrical energy.

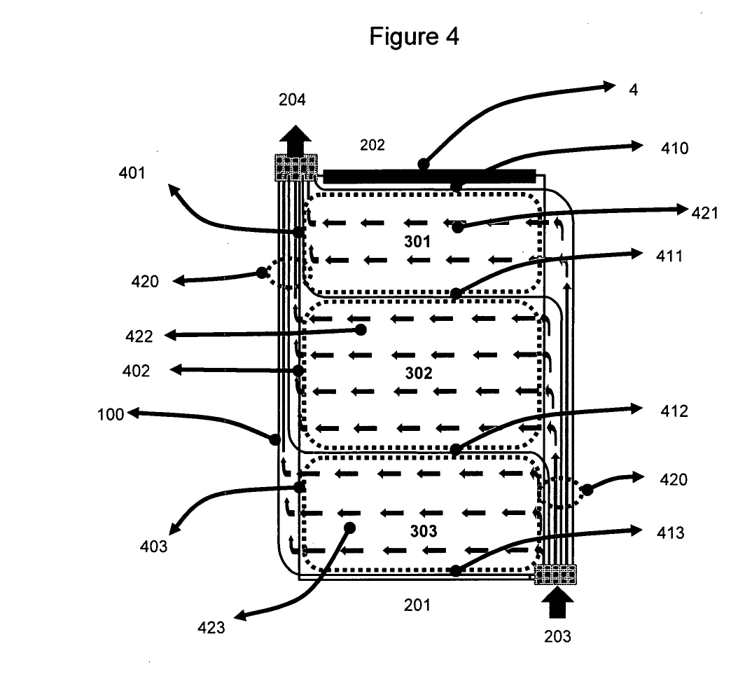

FIG. 4 illustrates an exemplary embodiment of converging system cooling (CSC) using system design specific cooling segments 401, 402, 403 for the server system main board 100 layout of the present invention. This design provides specific cooling segments 401, 402, 403 having individually controlled cooling airstream chambers for the server system main board 100.

As explained previously, the server system main board 100 is partitioned into specific electronic segments 301, 302, 303 driven by electrical requirements. As further explained, these electronic segments 301, 302, 303 show component specific electrical energy requirements. It is therefore a key requirement for the cooling system to provide individual cooling support for each defined segment 301, 302, 303. This individual cooling support is done via specific cooling segments 401, 402, 403 for each defined segment 301, 302, 303. For this reason, FIG. 4 illustrates the thermally decoupling of the electronic segments 301, 302, 303 by inserting airstream separating air guide fins 410, 411, 412, 413.

As previously mentioned, the front side 201 of the server system main board 100 as well as the rear side 202 of the server system main board 100 are designed to be airtight. The cooling segments 401, 402, 403 are supplied with fresh, cool air by individually dimensioned air entrance channels 420. As a consequence, the cool air intake 203 becomes subdivided by the air guide fins 410, 411, 412, 413 to provide separated specific airstreams 421, 422, 423 feeding the respective cooling segments 401, 402, 403. In addition, the cool air intake 203 redirects the incoming airstream by 90°, thus feeding the server system main board 100 with air.

The hot air exhaust 204 is provided on the opposite side of the cooling segments 401, 402, 403 from the cool air intake 203. At the hot air exhaust 204, the airstream is redirected a second time by 90°, thus leaving the air being exhausted from the hot air exhaust 204 in the original airstream direction.

The air guide fins 410, 411, 412, 413 guide air from the cool air intake 203 through contact with the server system main board 100 to the hot air exhaust 204. To provide the air turbulence and minimized aerodynamic resistance, the air guide fins 410, 411, 412, 413 as well as the cool air intake 203 and the hot air exhaust 204 provide an unruffled surface. The unruffled surface can include plastic molded sheets or polished metal sheets.

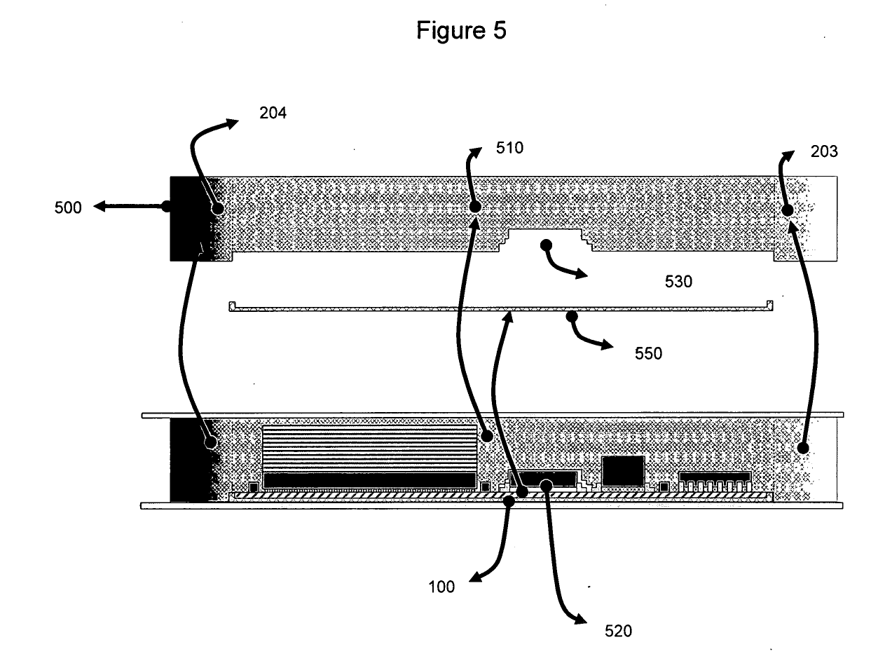

FIG. 5 illustrates an exemplary embodiment of an air guide fin of the converging system cooling (CSC) using a system-design specific cooling segment of the present invention.

For electrical reasons or layout effectiveness, it may become necessary to place an exemplary component 520 at a boundary crossing of an electronic segment 510. In this situation, an air guide fin, as shown by the exemplary embodiment illustrated by element 500 in FIG. 5, provides a ‘cut-out’ 530 representing the shape of the respective component 520, thus keeping the required segment airstream separation.

Depending on the system design, it may be required to as well separate the airstream underneath the server system main board 100. As exemplarily shown in FIG. 5, this can be accomplished using a corresponding bottom air guide fin 550 to the server system main board 100.

For cost effectiveness, as well as for ease of system assembly, the air guide fins, as well as the cool air intake ducts and the hot air exhaust ducts, can be made an integral portion of the system housing of the server system main board.

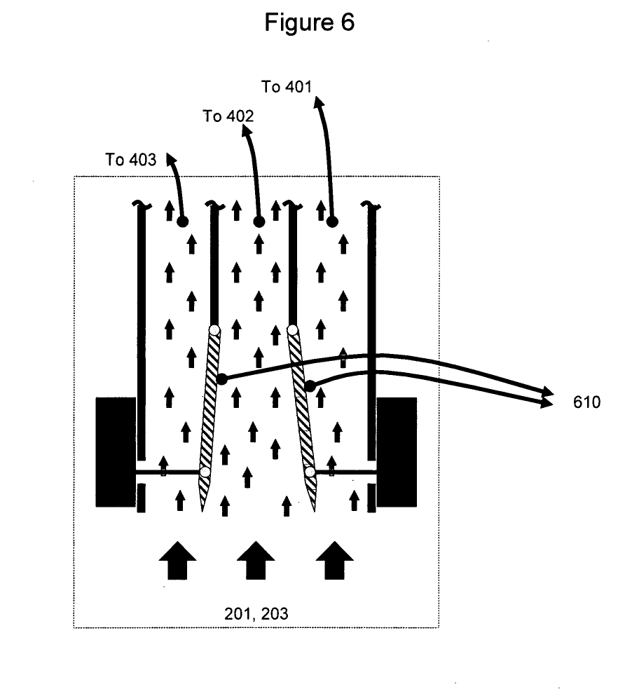

FIG. 6 illustrates an exemplary embodiment of the CSC airflow convergence control elements of the present invention. The CSC defined cooling segments 401, 402, 403 are already individually feeding the respective electronic components with cooling air as required specifically by the electronic segments 301, 302, 303. However, given this basic CSC design, it requires only a minor additional design detail to further allow reallocation of the given overall system airstream to respond to potentially varying cooling requirements in real-time.

FIG. 6 illustrates a simple mechanism to change the air duct entrance profile. In case e.g. a short time over-clocking (performance boost) of the server system main board 100 is required, the segment airflow control flaps 610 can be adjusted to redistribute the given airstream on demand. The basic design-specific thermal convergence can be complemented by control mechanisms converging segments 301, 302, 303 thermal requirements in real time.

This exemplary CSC feature can as well be used to quickly reduce the server system main board 100 temperature in predicted server system main board 100 idle times, thus allowing the server system main board 100 to start from a cool state when high performance is required again. The regulating parameter can be provided by dedicated air temperature sensors attached to the respective devices or by calculating an intelligent parameter predicting operating states of the system. In any case, CSC provides a simple but efficient convergence mechanism to distribute the cool airstream to extended requirements.

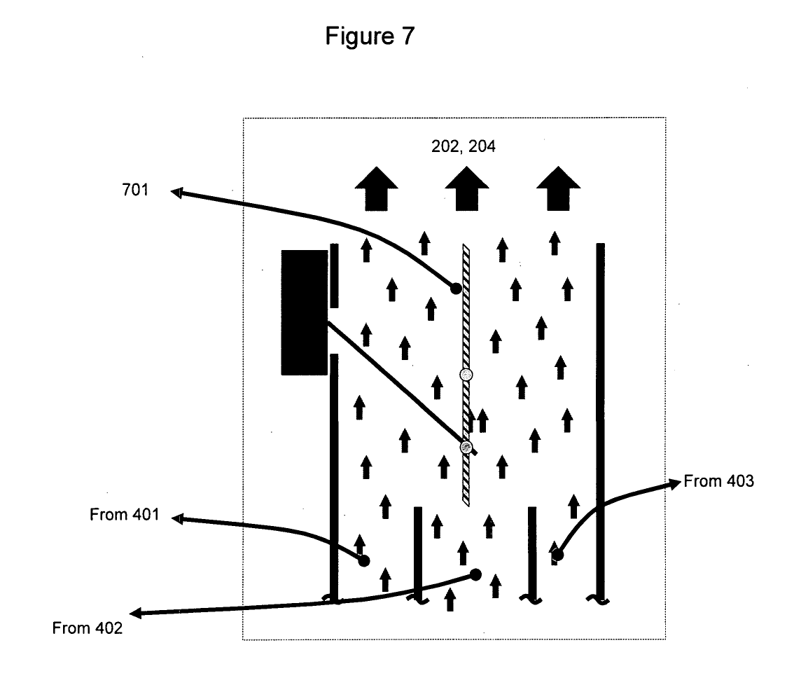

FIG. 7 illustrates an exemplary embodiment of the CSC airflow throttle element 701. As a further airstream regulation option, CSC can provide a feature to reduce or to even entirely lock portions of the hot air exhaust coming from specific electronic segments 301, 302, 303. This feature can be advantageous in situations when the server system main board 100 is temporarily shut down, in sleep mode, or in low power operation. The temporarily released cooling capacity can be utilized by the other servers within the cooling alliance in a rack, or the common cooling system can be temporarily reduced for energy savings. FIG. 7 shows a simple example solution utilizing a controllable exhaust throttle flap 701 allowing throttle or entirely locking the hot air exhaust 204 of the server system main board 100, thereby restricting a flow of hot air emanating from one of the cooling segments.

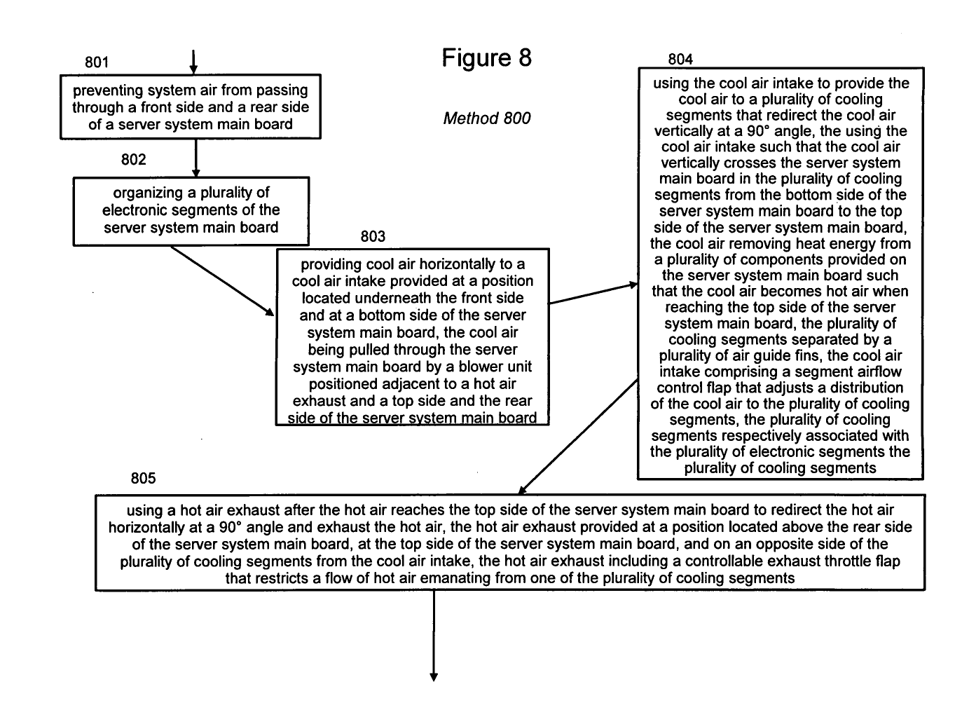

FIG. 8 illustrates an exemplary embodiment of a method 800 of the present invention. The method 800 of cooling a complex electronic system includes preventing (801) system air from passing through a front side and a rear side of a server system main board, organizing (802) a plurality of electronic segments of the server system main board, providing (803) cool air horizontally to a cool air intake provided at a position located underneath the front side and at a bottom side of the server system main board, the cool air being pulled through the server system main board by a blower unit positioned adjacent to a hot air exhaust and a top side and the rear side of the server system main board, using (804) the cool air intake to provide the cool air to a plurality of cooling segments that redirect the cool air vertically at a 90° angle, the using the cool air intake such that the cool air vertically crosses the server system main board in the plurality of cooling segments from the bottom side of the server system main board to the top side of the server system main board, the cool air removing heat energy from a plurality of components provided on the server system main board such that the cool air becomes hot air when reaching the top side of the server system main board, the plurality of cooling segments separated by a plurality of air guide fins, the cool air intake comprising a segment airflow control flap that adjusts a distribution of the cool air to the plurality of cooling segments, the plurality of cooling segments respectively associated with the plurality of electronic segments, and using (805) a hot air exhaust after the hot air reaches the top side of the server system main board to redirect the hot air horizontally at a 90° angle and exhaust the hot air, the hot air exhaust provided at a position located above the rear side of the server system main board, at the top side of the server system main board, and on an opposite side of the plurality of cooling segments from the cool air intake, the hot air exhaust including a controllable exhaust throttle flap that restricts a flow of hot air emanating from one of the plurality of cooling segments.

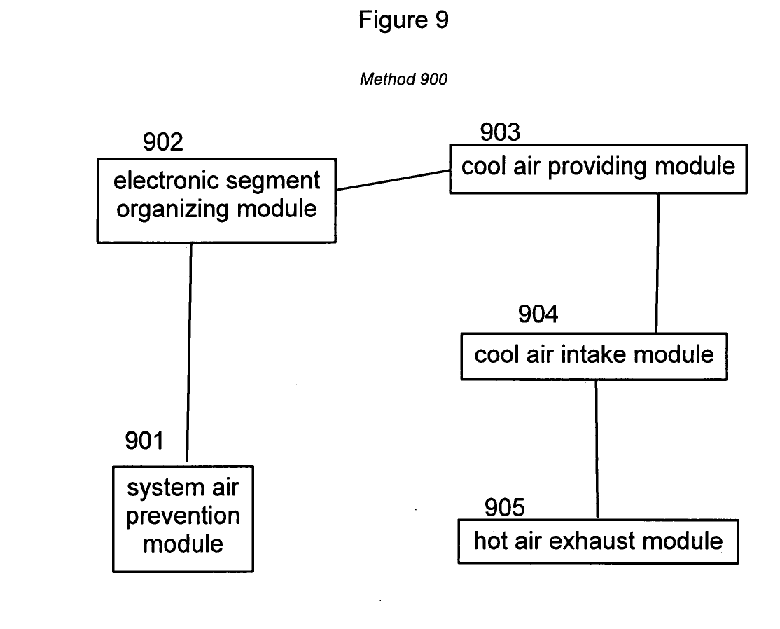

FIG. 9 illustrates an exemplary embodiment of a system 900 of the present invention. The system of cooling a complex electronic system includes a system air prevention module (901) for preventing system air from passing through a front side and a rear side of a server system main board, an electronic segment organizing module (902) for organizing a plurality of electronic segments of the server system main board, a cool air providing module (903) for providing cool air horizontally to the server system main board through a cool air intake provided at a position located underneath the front side and at a bottom side of the server system main board, the cool air being provided by a blower unit at a rear side of a server chassis, a cool air intake module (904) for using the cool air intake after the providing the cool air to separate the cool air into a plurality of cooling segments equaling and respectively associated with the plurality of electronic segments and to redirect the cool air vertically at a 90° angle, the using the cool air intake such that the cool air vertically crosses the server system main board in the plurality of cooling segments from the bottom side of the server system main board to a top side of the server system main board, the cool air removing heat energy from a plurality of components provided on the server system main board such that the cool air becomes hot air when reaching the top side of the server system main board, the plurality of cooling segments separated by a plurality of air guide fins, the cool air intake including a segment airflow control flap that adjusts a distribution of the cool air to the plurality of cooling segments, and a hot air exhaust module (905) for using a hot air exhaust after the hot air reaches the top side of the server system main board to redirect the hot air horizontally at a 90° angle and exhaust the hot air, the hot air exhaust provided at a position located above the rear side of the server system main board, at the top side of the server system main board, and on an opposite side of the plurality of cooling segments from the cool air intake, the hot air exhaust including a controllable exhaust throttle flap that restricts a flow of hot air emanating from one of the plurality of cooling segments.

Improvements and modifications can be made to the foregoing without departing from the scope of the present invention.

It will be appreciated by persons skilled in the art that the present invention is not limited to what has been particularly shown and described hereinabove. Rather, the scope of the present invention includes both combinations and sub-combinations of the various features described hereinabove, as well as variations and modifications thereof that are not in the prior art, which would occur to persons skilled in the art upon reading the foregoing description.

What is claimed is:

1. A method of cooling a complex electronic system, comprising:
preventing system air from passing through a front side and a rear side of a server system main board;
organizing a plurality of electronic segments of said server system main board;
providing cool air horizontally to a cool air intake provided at a position located underneath said front side and at a bottom side of said server system main board, said cool air being pulled through said server system main board by a blower unit positioned adjacent to a hot air exhaust and a top side and said rear side of said server system main board;
using said cool air intake to provide said cool air to a plurality of cooling segments that redirect said cool air vertically at a 90° angle, said using said cool air intake such that said cool air vertically crosses said server system main board in said plurality of cooling segments from said bottom side of said server system main board to said top side of said server system main board, said cool air removing heat energy from a plurality of components provided on said server system main board such that said cool air becomes hot air when reaching said top side of said server system main board, said plurality of cooling segments separated by a plurality of air guide fins, said cool air intake comprising a segment airflow control flap that adjusts a distribution of said cool air to said plurality of cooling segments, said plurality of cooling segments respectively associated with said plurality of electronic segments; and
using said hot air exhaust after said hot air reaches said top side of said server system main board to redirect said hot air horizontally at a 90° angle and exhaust said hot air, said hot air exhaust provided at a position located above said rear side of said server system main board, at said top side of said server system main board, and on an opposite side of said plurality of cooling segments from said cool air intake, said hot air exhaust comprising a controllable exhaust throttle flap that restricts a flow of hot air emanating from one of said plurality of cooling segments,
wherein said cool air and said hot air comprise an airstream,
wherein said cool air intake and said hot air exhaust utilize polished air guidance to prevent a resistance of said airstream, provide said airstream at a high speed, lower noise caused by said airstream, and reduce a loss of said cool air by said cool air intake, and
wherein said air guide fins, said cool air intake, and said hot air exhaust comprise an unruffled surface.
